(19) United States
(12) Patent Application Publication
(10) Pub. No.: US 2012/0307476 A1
(43) Pub. Date: Dec. 6, 2012

(54) CONTROL UNIT AND DRIVING APPARATUS USING THE SAME

(75) Inventors: Takashi MASUZAWA, Anjo-city (JP); Masashi Yamasaki, Obu-city (JP); Hiroshi Taki, Okazaki-city (JP)

(73) Assignee: DENSO CORPORATION, Kariya-city (JP)

(21) Appl. No.: 13/482,217

(22) Filed: May 29, 2012

(30) Foreign Application Priority Data
May 30, 2011 (JP) 2011-120272

(51) Int. Cl. H05K 9/00

(52) U.S. Cl. 361/816

(57) ABSTRACT

Power terminals of power modules are magnetically coupled to power-output terminals and power-input terminals. A heat sink has parallel surfaces, which are in parallel to the power modules and the power terminals. A magnetic field, which is generated by electric current flowing through switching devices and the power terminals, is cancelled by a magnetic field, which is generated by eddy current flowing in the heat sink.

### CROSS REFERENCE TO RELATED APPLICATION

This application is based on Japanese Patent Application No. 2011-120272 filed on May 30, 2011, the disclosure of which is incorporated herein by reference.

### TECHNICAL FIELD

The present invention relates to a control unit and a driving apparatus using the same for driving and controlling an operation of an electric motor.

### BACKGROUND

A three-phase electric motor is known in the art, according to which the electric motor is driven to rotate when three-phase alternating current is supplied thereto.

In a case that a power source for the three-phase electric motor is a direct-current power source having a predetermined voltage, it is necessary to provide a control unit having multiple switching devices, according to which current supply to stator coils is switched over so that stator-coil currents of different phases are supplied to respective stator coils (for example, three-phase coils). For example, switching devices are arranged at a heat radiating device, as disclosed in Japanese Patent Publication No. H03-89837.

In the above prior art, a magnetic field, which is generated by electric current flowing through the switching devices, may affect adverse influence on other electrical parts and/or components, such as connectors.

### SUMMARY OF THE DISCLOSURE

The present disclosure is made in view of the above disadvantages. It is an object of the present disclosure to provide a control unit and a driving apparatus using the same, according to which propagation of noise from switching devices is suppressed.

According to a feature of the present disclosure (for example, as defined in claim 1) a control unit for controlling an electric load has a power-input terminal, a power-output terminal, multiple switching devices, wiring portions, and a metal chassis.

The power-input terminal is connected to a power source. The power-output terminal is connected to the electric load. The multiple switching devices are provided between the power-input terminal and the power-output terminal for switching on or switching off power supply to the electric load. The wiring portions electrically connect the switching devices to the power-input terminal and the power-output terminal. The metal chassis supports the switching devices and has a parallel surface which is in parallel to the switching devices and the wiring portions. The wiring portions are magnetically coupled to at least one of the power-input terminal and the power-output terminal, when electric current flowing through the wiring portions is changed. The switching devices and the wiring portions are arranged so as to be in parallel to the parallel surface of the metal chassis, in order that a magnetic field generated by electric current flowing through the switching devices and the wiring portions is cancelled by a magnetic field generated by eddy current flowing in the metal chassis.

According to the above features, propagation of the magnetic field, which is generated by the electric current flowing through the switching devices and the wiring portions, can be suppressed. In other words, it is possible to suppress that the magnetic field (generated by the electric current flowing through the switching devices and the wiring portions) may affect adverse influences on other parts and/or components. Therefore, propagation of noises of the switching devices can be suppressed.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a schematic diagram showing a structure of a power steering apparatus for a vehicle according to a first embodiment of the present disclosure;

FIG. 2 is a schematic perspective view showing a driving apparatus according to the first embodiment of the present disclosure;

FIG. 3 is an exploded perspective view schematically showing the driving apparatus of the first embodiment;

FIG. 4 is a schematic top plan view when viewed in a direction IV in FIG. 2;

FIG. 5 is a schematic cross sectional view taken along a line V-V in FIG. 4;

FIG. 6 is a schematic cross sectional view taken along a line VI-VI in FIG. 4;

FIG. 7 is an enlarged view schematically showing a relevant portion indicated by VII in FIG. 6; and

FIG. 8 is a schematic cross sectional view showing a driving apparatus according to a second embodiment of the present disclosure.

### DETAILED DESCRIPTION OF THE EMBODIMENTS

The present invention will be explained by way of multiple embodiments with reference to the drawings. The same reference numerals are used throughout the embodiments for the purpose of designating the same or similar parts and components.

### First Embodiment

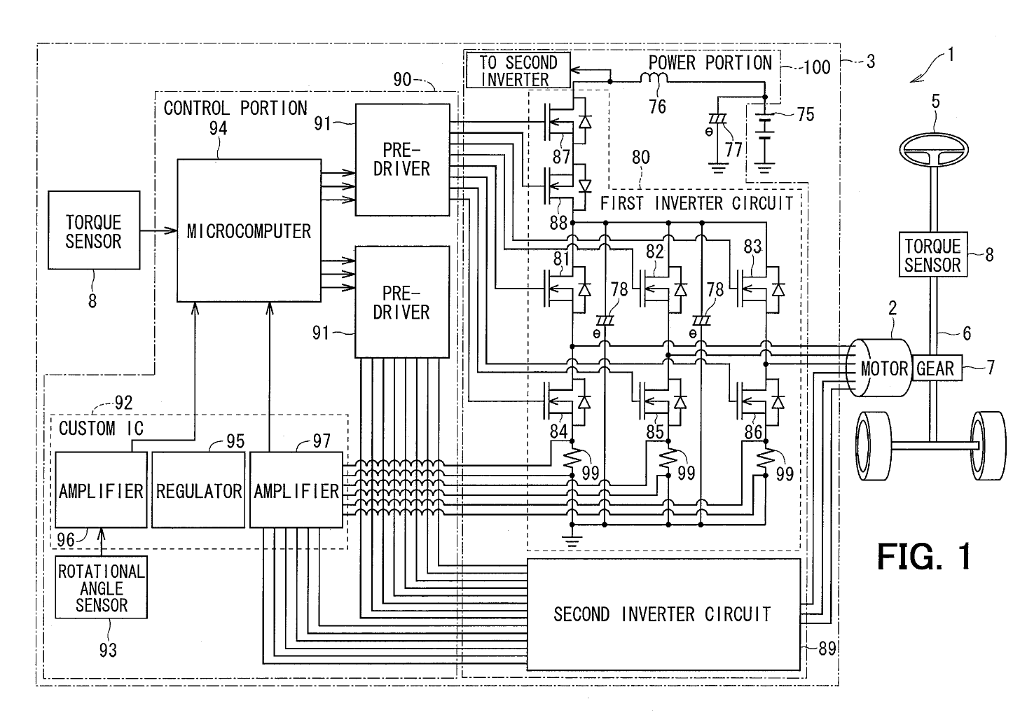

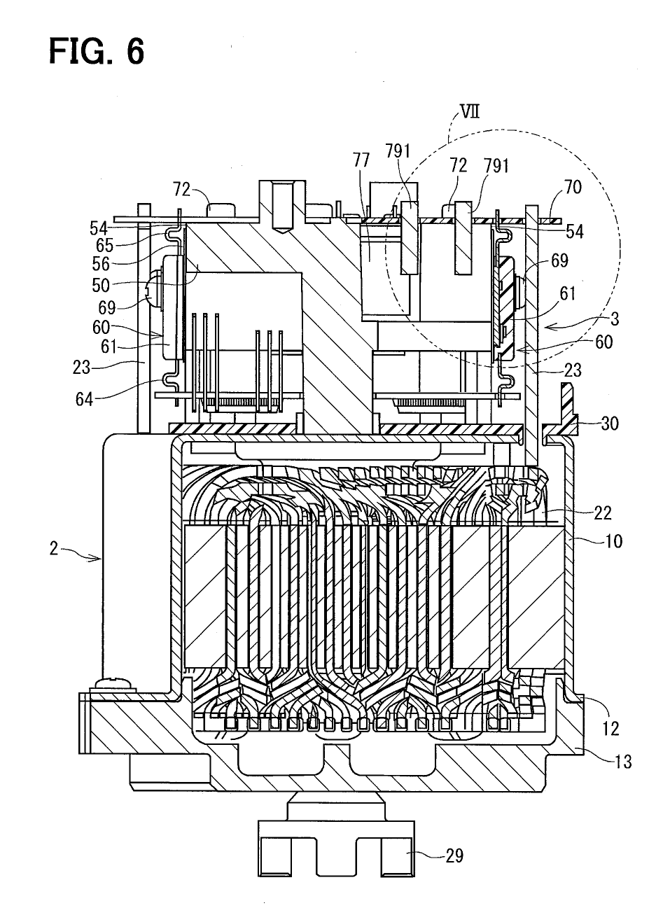

A driving apparatus 1 of a first embodiment of the present disclosure will be explained with reference to FIGS. 1 to 7. The driving apparatus 1 is applied to an electrical power steering device (EPS) for a vehicle. The driving apparatus 1 is composed of an electric motor 2 and a control unit 3.

An electrical configuration of the EPS will be explained with reference to FIG. 1.

As shown in FIG. 1, the driving apparatus 1 generates a rotational torque at a column shaft 6, which is a rotational shaft for a steering wheel 5 of a vehicle, via a gear of a gear box 7 provided in the column shaft 6, so as to assist a steering operation by the steering wheel 5. More in detail, when the steering wheel 5 is operated by a vehicle driver, a steering torque generated in the column shaft 6 is detected by a torque sensor 8 and information of a vehicle speed is obtained from CAN (Controller Area Network: not shown), so as to assist the steering operation of the steering wheel 5 by the vehicle driver. It is also possible to automatically control the operation of the steering wheel 5 not only for assisting the steering operation but also for keeping a driving lane of the vehicle on a highway, for guiding the vehicle to a parking spot in a car parking space, and so on, when the control of the vehicle is properly done by use of the driving apparatus 1.

The electric motor 2 is a three-phase brushless type motor for driving the gear (of the gear box 7) to rotate in a forward direction or a backward direction. Power supply to the electric motor 2 is controlled by the control unit 3, so that the operation of the electric motor 2 is controlled. The control unit 3 is composed of a power portion 100, through which driving current for the electric motor 2 flows, and a control portion 90 for controlling the operation of the electric motor 2.

The power portion 100 has a choke coil 76 provided in a power-supply line connected to a power source 75, a capacitor 77, and a pair of (first and second) inverter circuits 80 and 89. Since the structure of the inverter circuit 89 is identical to that of the inverter circuit 80, explanation will be made only for the first inverter circuit 80.

The first inverter circuit 80 has multiple transistors 81 to 86 of MOSFET (a metal-oxide-semiconductor field-effect transistor, hereinafter referred to as a MOS transistor). In the MOS transistors 81 to 86, a source-drain path is turned on or turned off depending on a gate potential. The MOS transistors 81 to 86 are also collectively referred to as switching devices.

A drain of the MOS transistor 81 is connected to the power-supply line, while a source thereof is connected to a drain of the MOS transistor 84. A source of the MOS transistor 84 is connected to the ground via a shunt resistor 99. A connecting point of the MOS transistors 81 and 84 is connected to a U-phase coil of the electric motor 2.

In a similar manner, a drain of the MOS transistor 82 is connected to the power-supply line, while a source thereof is connected to a drain of the MOS transistor 85. A source of the MOS transistor 85 is connected to the ground via the shunt resistor 99. A connecting point of the MOS transistors 82 and 85 is connected to a V-phase coil of the electric motor 2.

A drain of the MOS transistor 83 is likewise connected to the power-supply line, while a source thereof is, connected to a drain of the MOS transistor 86. A source of the MOS transistor 86 is connected to the ground via the shunt resistor 99. A connecting point of the MOS transistors 83 and 86 is connected to a W-phase coil of the electric motor 2.

The first inverter circuit 80 has power-source relays 87 and 88, which are made of MOSFET in a similar manner to the MOS transistors 81 to 86. The power-source relays 87 and 88 are provided between the power source 75 and the MOS transistors 81 to 83 in order to cut off the driving current flowing from the first inverter circuit 80 to the electric motor 2 in case of a malfunction. The power-source relay 87 is provided for the purpose of cutting off the driving current to the electric motor 2 in case of the malfunction, such as, a disconnection, a short-circuit and so on. The power-source relay 88 is provided for the purpose of preventing electrical current from flowing in a reversed direction, when electrical parts (such as, capacitors 78 and so on) are accidentally connected in a reversed condition, to thereby protect such electrical parts.

The shunt resistors 99 are electrically connected between each of the MOS transistors 84 to 86 and the ground. Electric potential between both ends of each shunt resistor 99 or electric current flowing through each of the shunt resistors 99 is detected so as to detect the driving current supplied to the respective U-phase, V-phase and W-phase coils of the electric motor 2.

The choke coil 76 and the capacitor 77 are electrically connected between the power source 75 and the power-source relay 87. The choke coil 76 and the capacitor 77 form a filter circuit so as to reduce noise, which may be propagated from other electrical apparatuses and/or devices having the common power source 75, and/or to reduce noises which may be propagated from the driving apparatus 1 to the other apparatuses and/or devices.

Each of the capacitors 78 is connected at its one side to the power supply line for the MOS transistors 81 to 83, while the other side thereof is connected to a ground line for the MOS transistors 84 to 86. The capacitors 78 store electric charge so as to assist power supply to the MOS transistors 81 to 86 and/or remove noise components, such as surge voltages.

The control portion 90 is composed of pre-driver circuits 91, a custom IC 92, a rotational angle sensor 93 for detecting a rotational angle of a shaft of the electric motor 2 (explained below) and a micro-computer 94. The custom IC 92 (a functional block) includes a regulator 95, an amplifying portion 96 for a rotational-angle sensor signal, an amplifying portion 97 for detected voltage and so on.

The regulator 95 is a stabilization circuit for stabilizing the power supply to the respective portions. For example, the micro-computer 94 operates with a stabilized predetermined voltage (for example, 5 volt) from the regulator 95.

A sensor signal from the rotational angle sensor 93 is inputted to the amplifying portion 96. The rotational angle sensor 93 detects a rotational position of the electric motor 2 and such detected rotational position signal is supplied to the amplifying portion 96. The rotational position signal (that is, a rotational-angle sensor signal) is amplified by the amplifying portion 96 and then supplied to the micro-computer 94.

The amplifying portion 97 detects the voltage across the shunt resisters 99 and amplifies the detected voltage to output it to the micro-computer 94.

The rotational position signal of the electric motor 2 and the voltage across the shunt resisters 99 are inputted to the micro-computer 94. The steering torque signal of the torque sensor 8 provided in the column shaft 6 is also inputted to the micro-computer 94. Furthermore, the information of the vehicle speed is inputted to the micro-computer 94 via the CAN. When the steering torque signal and the information of the vehicle speed are inputted to the micro-computer 94, the micro-computer 94 controls the inverter circuit 80 via the pre-driver circuit 91 in accordance with the rotational position signal, so as to assist the steering operation of the steering wheel 5 depending on the vehicle speed.

More in detail, the micro-computer 94 controls the inverter circuit 80 by changing on-off conditions of the MOS transistors 81 to 86 via the pre-driver circuit 91. Since each of the gates of the MOS transistors 81 to 86 is connected to the respective (six) output terminals of the pre-driver circuit 91, the on-off condition of each MOS transistor 81 to 86 is switched over when the gate potential for the respective MOS transistors 81 to 86 is controlled by the pre-driver circuit 91.

The micro-computer 94 controls the inverter circuit 80 based on the voltage across the shunt resistors 99 from the detected-voltage amplifying portion 97 so as to generate the three-phase alternating current of a substantially sinusoidal waveform, which is supplied to the electric motor 2 as the driving current. The control portion 90 controls the second inverter circuit 89 in the same manner to the first inverter circuit 80.

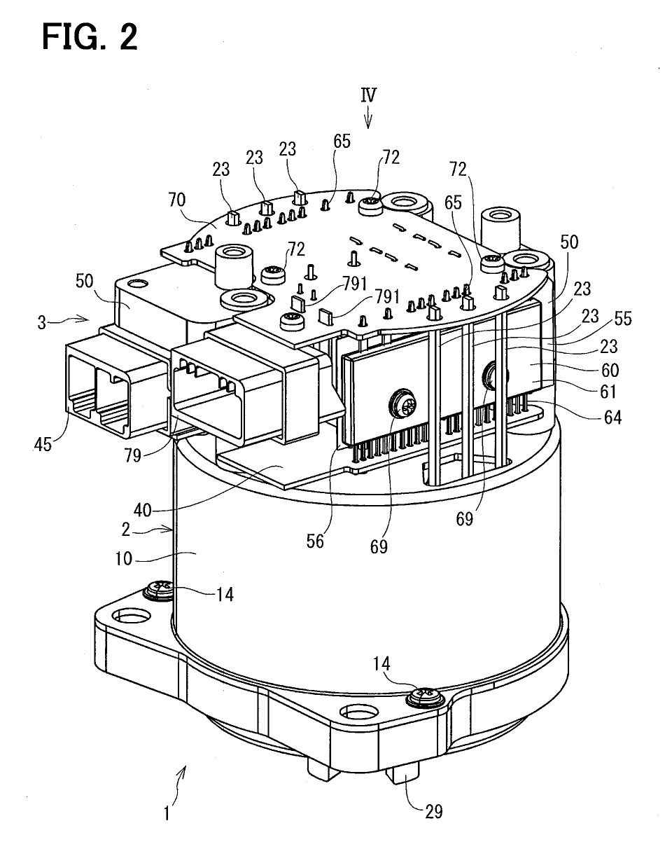

Now, a structure of the driving apparatus 1 will be explained with reference to FIGS. 2 to 7.

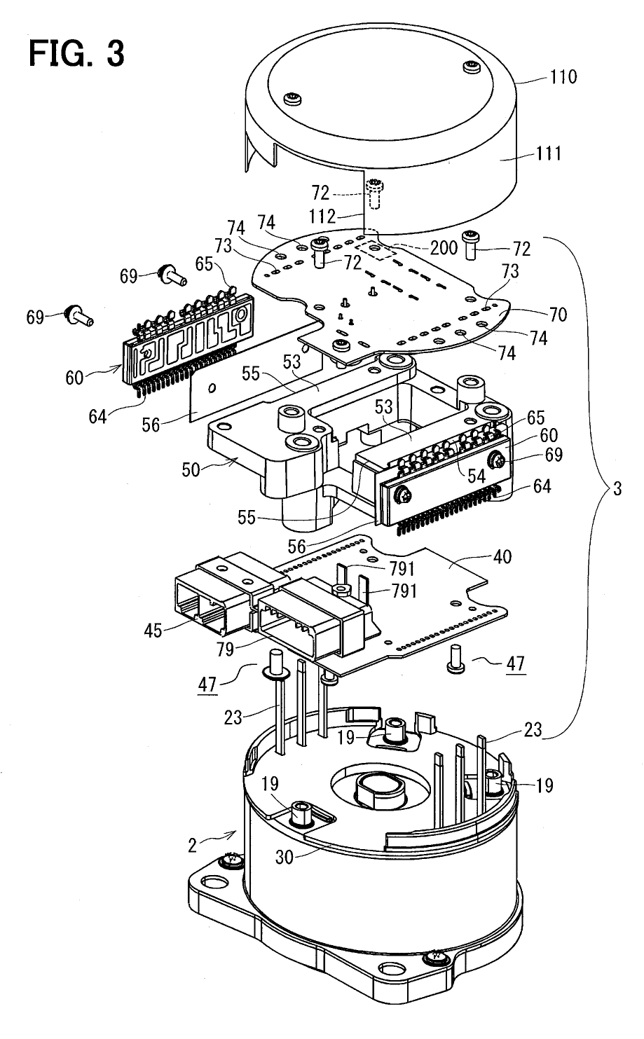

As shown in FIGS. 2 and 3, the driving apparatus 1 has a laminated structure, wherein the control unit 3 is provided at one axial end of the electric motor 2 (at an upper end of the electric motor 2 in the drawings).

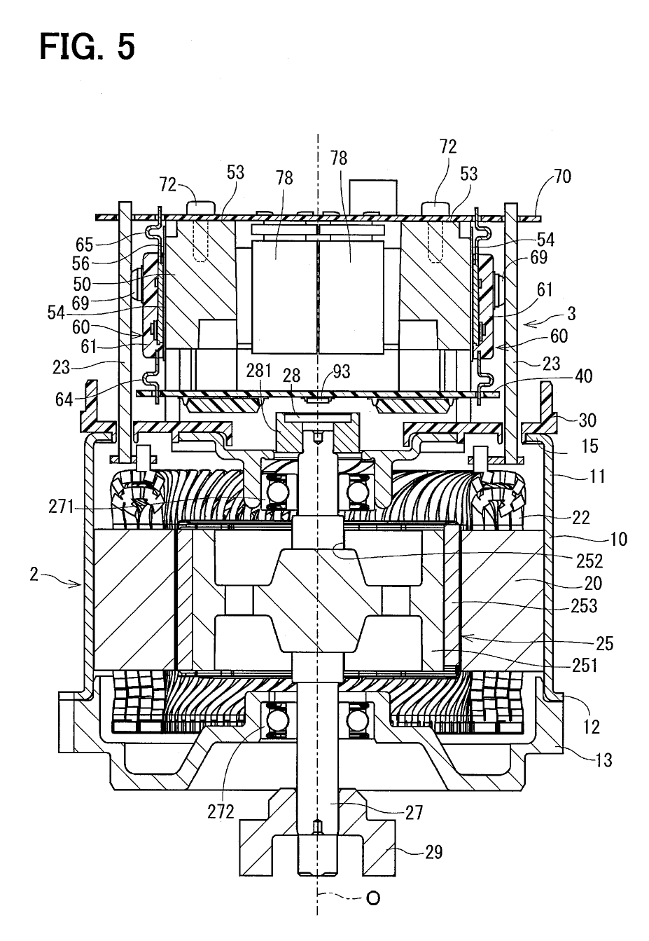

A structure of the electric motor 2 will be explained with reference to FIG. 5. The electric motor 2 is composed of a motor casing 10, a stator 20 having a stator coil 22, a rotor 25, a shaft 27 and so on. The motor casing 10 is made of iron or the like formed in a cup shape having a cylindrical wall 11 and an axial end wall 15 (on an axial side of the electric motor 2 neighboring to the control unit 3). A flanged portion 12 is formed at an axial end of the cylindrical wall 11 (at a lower end side in the drawings). An end frame 13 made of, for example, aluminum is fixed to the flanged portion 12 by multiple bolts 14 (as sown in FIG. 2).

The stator 20 is arranged in an inside of the motor casing 10. The stator 20 has multiple projected poles, each of which is projected in a radial inward direction of the motor casing 10. The projected poles are formed by a laminated iron core, which is made of multiple magnetic thin plates. The stator 20 has insulators (not shown) at both axial ends of the laminated iron core. The stator coil 22 is wound on the insulators. A number of magnetic thin plates forming the laminated iron core can be changed depending on a required output for the electric motor 2. In other words, the output of the electric motor 2 can be changed by changing not a radial dimension but an axial length (the number of the magnetic thin plates) of the electric motor 2. It is, therefore, advantageous when the driving apparatus 1 is mounted in a space having a limited radial dimension.

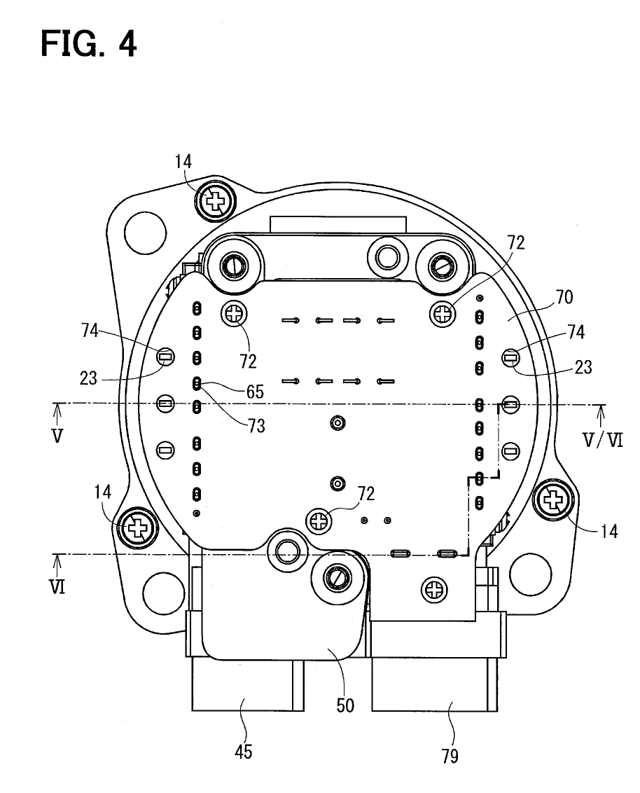

The stator coil 22 is composed of a three-phase winding structure having the U-phase coil, the V-phase coil and the W-phase coil. Six stator-coil terminals 23 (power-output terminals) are pulled out from the stator coil 22 (FIG. 2). The stator-coil terminals 23 pass through respective terminal pull-out openings formed in the motor casing 10 and extend in a direction toward the control unit 3 (in an upper direction in the drawings). The stator-coil terminals 23 further extend along outer peripheral sides of a control board 40 and power modules 60 and then electrically connected a power board 70. In other words, when viewed in an axial direction of the electric motor 2 (more exactly, when viewed in the direction IV in FIG. 2), the stator-coil terminals 23 are located at the outer peripheral sides of the respective power modules 60 in a radial direction, as shown in FIG. 4. In other words, the stator-coil terminals 23 stride over each of the power modules 60 in an area of the outer peripheral side of the power module 60 in the radial direction and extend to the power board 70.

The rotor 25 is movably arranged in a radial inside of the stator 20, so that the rotor 25 is rotatable relative to the stator 20. The rotor 25 is made of magnetic material (such as, iron) and formed in a cylindrical shape. The rotor 25 has a rotor core 251 and a permanent magnet 253 provided at an outer periphery of the rotor core 251, wherein the magnet 253 is magnetized in such a manner that N-poles and S-poles are alternately arranged in a circumferential direction.

The shaft 27 is fixed to a shaft hole 252 formed at a center of the rotor core 251. The shaft 27 is rotatably supported by a bearing 271 provided at the motor casing 10 and a bearing 272 provided at the end frame 13. Therefore, the shaft 27 is rotatable together with the rotor 25 relative to the stator 20.

As shown in FIG. 5, a magnet 28 is attached to an axial end of the shaft 27 (an upper end in the drawing), that is, a side to the control unit 3. The magnet 28 forms apart of a detecting portion and is rotated together with the shaft 27. The magnet 28 is fixed to a magnet holder 281, which is attached to the axial end of the shaft 27, so that the magnet 28 is coaxially attached to the shaft 27. The magnet 28 is exposed on a side to the control unit 3 so as to face to the control board 40. According to the present embodiment, the shaft 27 does not extend through the control board 40. The magnet 28 is therefore located at a position close to the control board 40.

As shown in FIGS. 2, 3 and 5, the shaft 27 has an output portion 29 at the other axial end thereof on a side opposite to the control unit 3. The gear box 7 having therein the gear is provided on the side of the output portion 29 of the shaft 27. The output portion 29 is engaged with the gear of the gear box 7. A rotational force of the shaft 27 is transmitted from the output portion 29 to the gear, so that an operational power is applied to the column shaft 6.

The control unit 3 will be explained with reference to FIGS. 3 to 7. The control unit 3 is composed of the control board 40, a heat sink 50 (that is, a metal chassis), the power modules 60, the power board 70 and so on.

Almost all of the parts and components for the control unit 3 (except for a control connector 45 and a power connector 79) is accommodated in a motor-casing corresponding space, which is a space formed above the motor casing 10 and projected in the axial direction. The control connector 45 and the power connector 79 are connected to outside apparatuses and/or devices. As shown in FIG. 3, the control board 40, the heat sink 50, the power modules 60 and the power board 70 are arranged in this order from the side of the electric motor 2 in the axial (upward) direction of the electric motor 2. In other words, the motor casing 10, the control board 40, the heat sing 50 and the power modules 60, the power board 70 are arranged in this order in the axial direction.

The control board 40 is made of, for example, a four-layered board formed of glass-epoxy boards. The control board 40 is formed in a plate shape, so that the control board 40 is accommodated in the motor-casing corresponding space. The control board 40 is fixed to the heat sink 50 by screws 47 from the side of the electric motor 2.

Various, kinds of electric and/or electronic parts for the control portion 90 are mounted on the control board 40. The pre-driver circuits 91, the custom IC 92, the micro-computer 94 (shown in FIG. 1) are mounted to one of surfaces of the control board 40 on an opposite side to the electric motor 2. The rotational angle sensor 93 is mounted to the other surface of the control board 40 facing to the electric motor 2. The rotational angle sensor 93 is located at a position opposing to the magnet 28. The magnet 28 and the rotational angle sensor 93 are coaxially arranged with the shaft 27. The rotational angle sensor 93 detects a rotational angle of the shaft 27 by detecting a change of a magnetic field in accordance with the rotation of the magnet 28, which is rotated together with the shaft 27.

Multiple through-holes, to which control terminals 64 of the power modules 60 are respectively connected, are formed in the control board 40 along its outer peripheral sides. The control connector 45 is provided on the control board 40 in such a way that an outside corresponding connector or plug (not shown) is inserted into the control connector 45 in a radial inward direction of the electric motor 2. The signals from the torque sensor 8, the CAN and so on are inputted to the control unit 3 via the control connector 45.

The heat sink 50 (the metal chassis) is made of material having high heat conductivity, such as aluminum.

The heat sink 50 has a pair of heat receiving portions 55, each of which has a parallel surface 54 opposing to the stator-coil terminals 23 pulled out from the motor casing 10 and a contacting surface 53 formed on the side opposite to the electric motor 2 (on an upper side of the respective heat receiving portion 55). Each of the heat receiving portions 55 is arranged in a direction, which extends from the axial end wall 15 of the motor casing 10 in the axial direction, namely which is almost perpendicular to the axial end wall 15. Each of the parallel surfaces 54 is formed in a direction, which is in parallel to a rotational axis 0 of the electric motor 2.

Each of the power modules 60 is vertically arranged in parallel to the shaft 27 at an outer side of each parallel surface 54 of the heat sink 50 in the radial direction of the electric motor 2. Each of the power modules 60 is formed in an almost flat rectangular shape. An inner-side flat surface of the power module 60 is arranged to face to the parallel surface 54 of the heat sink 50 (namely, in parallel to the parallel surface). In other words, the inner-side flat surface of the power module 60 is perpendicular to a virtual plane, which is perpendicular to the rotational axis 0 of the electric motor 2.

A heat radiating sheet 56 is provided between each power module 60 and the parallel surface 54 of the heat sink 50. Each of the power modules 60 is fixed to the heat sink 50 via the heat radiating sheet 56 by screws 69. The power modules 60 are held by the heat sink 50 via the heat radiating sheets 56 and thereby heat generated in the power modules 60 upon the power supply thereto is transmitted (radiated) to the heat sink 50 via the heat radiating sheets 56.

Each of the power modules 60 has the MOS transistors 81 to 86, which are switching devices for controlling the power supply to the stator coil 22. In each of the power modules 60, semiconductor chips for the MOS transistors 81 to 88 (corresponding to the switching devices and the power-source relays) as well as the shunt resistors 99 are mounted to copper wiring patterns, they are electrically connected to wires or the like, and they are resin-molded to form a molded portion 61. In other words, the switching devices 81 to 86 are arranged on such a plane (a switching-device plane), which intersects with the virtual plane perpendicular to the rotational axis 0 of the electric motor 2. In the present embodiment, the switching-device plane is perpendicular to the virtual plane.

A relationship between the power modules 60 and the circuit configuration of FIG. 1 will be explained. One of the power modules 60 corresponds to the first inverter circuit 80 and includes the MOS transistors 81 to 86, the power-source relays 87 and 88 and the shunt resistors 99. The other of the power modules 60 corresponds to the second inverter circuit 89 and likewise includes the MOS transistors, the power-source relays and the shunt resistors.

According to the present embodiment, therefore, one of the power modules 60 corresponds to the inverter circuit of one power supply and control system. In each of the power modules 60, the MOS transistors 81 to 86 forming the inverter circuit 80 (or 89) are arranged in parallel to the parallel surface 54 of the heat sink 50. One power module 60 of one power supply and control system is arranged at one heat receiving portion 55.

Each of the power modules 60 has the control terminals 64 outwardly projecting from the molded portion 61 in a direction to the control board 40 and power terminals 65, which are also outwardly projecting from the molded portion 61 to the power board 70 and also referred to as wiring portions.

The control terminals 64 are formed at a lower side of the molded portion 61, that is, the side of the molded portion 61 in perpendicular to the parallel surface 54. The power terminals 65 (the wiring portions) are formed at an upper side (an opposite side) of the molded portion 61.

According to the present embodiment, the power module 60 is vertically arranged to the parallel surface 54 of the heat sink 50 (the heat receiving portion 55), so that the control terminals 64 extend to the control board 40 while the power terminals 65 extend to the power board 70. As above, the power module 60, the control terminals 64 and the power terminals 65 (the wiring portions) are provided in parallel to the parallel surface 54. The MOS transistors and the power terminals 65 in the power module 60 are magnetically coupled to the stator-coil terminals 23 (the power-output terminals).

Each of the control terminals 64 is inserted into respective through-holes formed in the control board 40 and electrically connected to the control board 40 by soldering or the like. The control signals are outputted from the control board 40 to the power modules 60 via the control terminals 64.

Each of the power terminals 65 is inserted into respective through-holes 73 formed in the power board 70 and electrically connected to the power board 70 by soldering or the like. The driving current for the stator coil 22 is supplied to the power modules 60 via the power terminals 65.

According to the present embodiment, a small electric current (for example, 200 mA) flows in the control board 40 for controlling an operation of the electric motor 2, while a large electric current (for example, 80 A) flows in the power board 70 for driving the electric motor 2. Therefore, the power terminals 65 are made larger than the control terminals 65.

The power board 70 is made of, for example, a four-layered printed circuit board of glass-epoxy boards, wherein copper wiring patterns are formed. The power board 70 (also referred to as the printed circuit board) is formed in such a flat plate shape that the power board 70 is accommodated in the motor-casing corresponding space. The power board 70 is fixed to the heat sink 50 (the heat receiving portions 55) by screws 72 from a side opposite to the electric motor 2.

The power board 70 is thereby brought into contact with the contacting surfaces 53 of the heat receiving portions 55 (as shown in FIGS. 3 and 5). The power board 70 is electrically connected to the heat receiving portions 55 by the screws 72.

In the present embodiment, the screws 72 are electrically connected to a ground wiring pattern 200 (a ground portion), through which the power board 70 is electrically connected to the ground. Therefore, the heat sink 50 is electrically connected to the ground wiring pattern 200 (the ground portion) of the power board 70. Power wiring patterns, through which the driving current for the stator coil 22 flows, are formed in the power board 70.

The through-holes 73, through which the power terminals 65 of the power modules 60 are respectively inserted, are formed in the power board 70. Multiple through-holes 74, through which the stator-coil terminals 23 are respectively inserted, are also formed in the power board 70 at the outer sides of the through-holes 73. Each of the stator-coil terminals 23 is inserted into the respective through-holes 74 and electrically connected to the power board 70 by soldering or the like, so that the stator-coil terminals 23 are electrically connected to the power modules 60 via the power board 70.

The choke coil 76 and capacitors 77 and 78 are mounted to the power board 70 on the side (the lower side in the drawing) facing to the electric motor 2.

The choke coil 76 and capacitors 77 and 78 are arranged in a space formed in an inside of the heat sink 50. In addition, the choke coil 76 and capacitors 77 and 78 as well as the power connector 79 are located between the power board 70 and the control board 40 in the axial direction.

The power connector 79 is connected to the power board 70. The power connector 79 is arranged on the side of the power board 70, on which the control terminal 45 connected to the control board 40 is arranged, in a side-by-side condition with the control terminal 45. The power connector 79 is connected to the power board 70 in such a way that an outside corresponding connector connected to the power source 75 is inserted into the power connector 79 in a radial inward direction of the electric motor 2. The power connector 79 has power-input terminals 791 connected to the power board 70. The electric power from the power source 75 is supplied to the power board 70 via the power connector 79. The electric power from the power source 75 is further supplied to the stator coil 22 of the stator 20 via the power connector 79, the power board 70, the power modules 60 and the stator-coil terminals 23 (the power-output terminals).

In the present embodiment, the power-output terminals 23 and the power terminals 65 are overlapped with each other in a radial direction. The MOS transistors in the power modules 60 and the power terminals 65 are magnetically coupled to the power-input terminals 791.

A cover member 110 is made of magnetic material, such as iron, for preventing electric field and magnetic field from leaking from the control unit 3 to its outside and also preventing dust from going into the inside thereof. The cover member 110 is formed in a cylindrical cup shape having a diameter almost equal to that of the electric motor 2 and having an open end on a side (a lower side in the drawing) to the electric motor 2. An open side portion 112 is formed in a side wall 111 of the cover member 110 at such a position, at which the control connector 45 and the power connector 79 are located. The open side portion 112 is formed in such a shape corresponding to shapes of the control connector 45 and the power connector 79.

In the present embodiment, since the control connector 45 is provided at such a position, which is closer to the electric motor 2 than a position of the power connector 79, a step portion is formed in the open side portion 112 corresponding to such positions of the control and power connectors 45 and 79. The control connector 45 and power connector 79 outwardly extend from the open side portion 112 in the radial direction and connected to the power source 75 and other electric and/or electronic apparatus and devices, which are located outside of the driving apparatus 1.

A holding member 30 is provided between the electric motor 2 and the control unit 3. The holding member 30 is formed in an almost disc shape having a diameter almost equal to that of the motor casing 10. The holding member 30 is made of resin.

An operation of the driving apparatus 1 will be explained.

The micro-computer 94 mounted on the control board 40 generates pulse signals, which are produced by PWM control and based on the signals from the rotational angle sensor 93, the torque sensor 8, the shunt resistors 99 and so on, via the pre-driver circuits 91, so that the steering operation of the steering wheel 5 is assisted depending on the vehicle speed.

The pulse signals are inputted, via the control terminals 64, to the first and second inverter circuits 80 and 89 of the two power supply and control systems, which are provided in the respective power modules 60, so as to control the operations of switch-on and switch-off of the MOS transistors 81 to 86. As a result, the driving current of the sinusoidal wave of different phase is supplied to each of the phase coils of the stator coil 22, so that rotating magnetic field is generated. The rotor 25 and the shaft 27 are integrally rotated by the rotating magnetic field. Then, the driving force is outputted from the output portion 29 to the gear box 7 of the column shaft 6 so as to assist the steering operation of the steering wheel 5 by the vehicle driver.

In other words, the electric motor 2 is driven to rotate by the driving current to the stator coil 22. In this meaning, the driving current is also the driving current for driving the electric motor 2.

The driving apparatus 1 of the first embodiment has the following advantages:

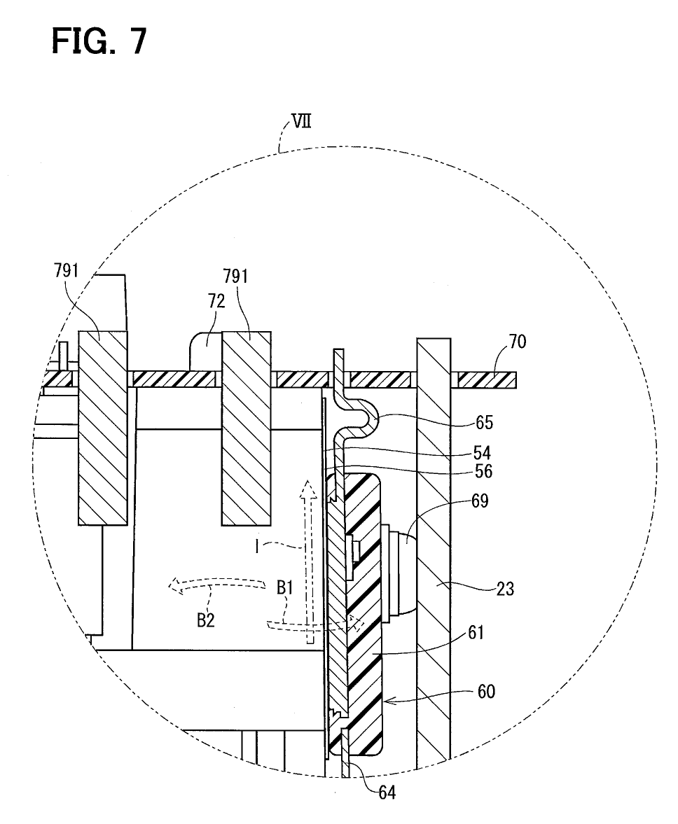

(1) According to the present embodiment, the MOS transistors 81 to 86 (the switching devices) and the power terminals 65 (the wiring portions) of the power modules 60 are arranged to be in parallel to the parallel surfaces 54 of the heat sink 50. When the on-off conditions of the MOS transistors 81 to 86 are changed, in other words, when electric current “I” flowing through the MOS transistors 81 to 86 is turned on or turned off, eddy current is generated to flow in the heat sink 50 due to electromagnetic induction. The eddy current flowing in the heat sink 50 generates a magnetic field “B2”, which may encumber a change of a magnetic field “B1” which is generated by the current flow through the MOS transistors 81 to 86. Namely, the magnetic field “B1” generated by the electric current “I” flowing through the MOS transistors 81 to 86 and the power terminals 65 and the magnetic field “B2” generated by the eddy current flowing through the heat sink 50 cancel each other, as shown in FIG. 7. As a result, it is possible to suppress propagation of the magnetic field “B1”, which is generated by the electric current “I” flowing through the MOS transistors 81 to 86 and the power terminals 65. In other words, it is possible to suppress an adverse influence of the magnetic field “B1” (generated by the electric current “I” flowing through the MOS transistors 81 to 86 and the power terminals 65) to the control connector 45, the power connector 79, the electronic parts and so on.

(2) According to the present embodiment, the stator-coil terminals 23 (the power-output terminals) are electrically connected to the power terminals 65 (the wiring portions) of the power modules 60 via the power board 70. According to such structure, it is possible to carry out a process of electrical connection between the power terminals 65 and the power board 70 and between the stator-coil terminals 23 and the power board 70 by one step. A manufacturing process can be thereby simplified.

(3) According to the present embodiment, the power board 70 is in contact with the contacting surfaces 53 of the heat receiving portions 55 of the heat sink 50. It is possible to suppress the propagation of the magnetic field (which is generated by the electric current flowing through the MOS transistors 81 to 86 and the power terminals 65) to the control connector 45 and the power connector 79 via a space between the power board 70 and the heat sink 50. It is, thereby, possible to increase shield effect of the heat sink 50. In other words, the effect for suppressing the adverse influence of the magnetic field (which is generated by the electric current flowing through the MOS transistors 81 to 86 and the power terminals 65) to the control connector 45 and the power connector 79 can be increased.

(4) According to the present embodiment, the heat sink 50 is electrically connected to the ground wiring pattern 200 (the ground portion), through which the power board 70 is electrically connected to the ground. According to such a structure, a loop of a pathway, through which the electric current (generating the magnetic field) flows, can be made larger. In addition, since the heat sink 50 is connected to the ground wiring pattern 200 (the ground portion) for the power board 70, impedance for the ground of the power board 70 can be reduced. As a result, performance of the electric circuit can be stabilized and noise generated by the switching devices (the MOS transistors 81 to 86) can be reduced.

(5) According to the present embodiment, the MOS transistors 81 to 88 of the inverter circuit 80 of one power supply and control system are molded in one molded portion 61. Workability for an assembling process can be thereby improved.

(6) According to the present embodiment, the electric motor 2, the control board 40, the heat sink 50 and the power modules 60, and the power board 70 are arranged in this order in the axial direction. The power modules 60 are arranged to be in parallel to the rotational axis 0 of the electric motor 2. In addition, the power-output terminals 23 (the stator-coil terminals) and the power terminals 65 (the wiring portions) of the power modules 60 are overlapped with each other in the radial direction. As a result, a physical size of the driving apparatus 1 in the radial direction can be made smaller. Furthermore, connecting portions of the power terminals 65, the power-output terminals 23 (the stator-coil terminals) and the power-input terminals 791 to the power board 70 are located at such portions, which are close to an axial end of the driving apparatus 1. It is easier to electrically connect those terminals 65, 23, 791 to the power board 70. In addition, since those connecting portions are located at the positions close to the axial end of the driving apparatus 1, it is easier to repair the driving apparatus 1 even if the driving apparatus 1 may become out of order.

### Second Embodiment

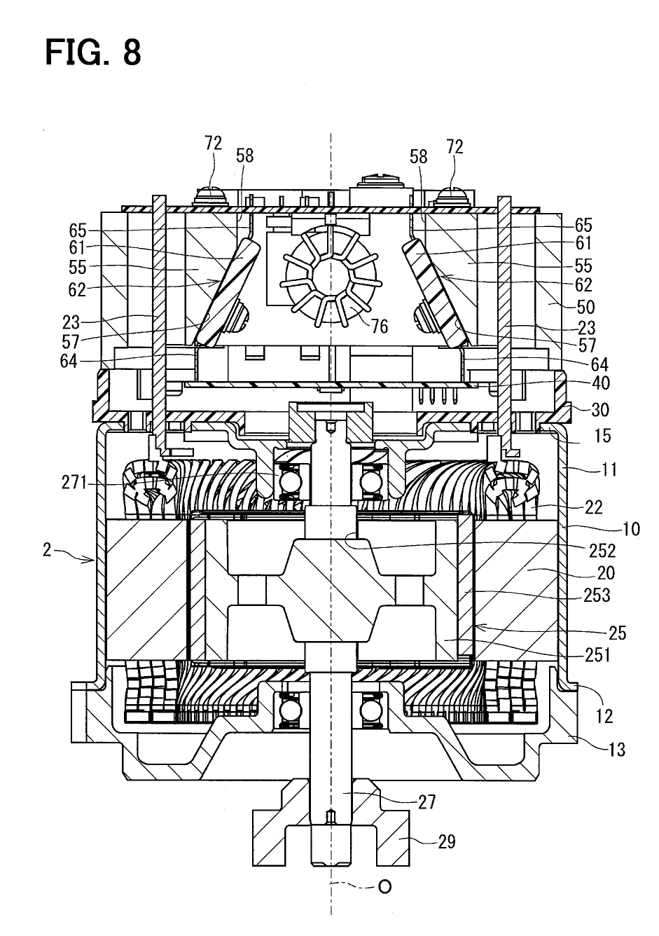

A driving apparatus according to a second embodiment of the present disclosure will be explained with reference to FIG. 8.

As shown in FIG. 8, an inclined surface 57 and a vertical surface 58 are formed at a radial-inside surface of each heat receiving portion 55 of the heat sink 50. The inclined surface 57 is inclined with respect to the rotational axis 0 of the electric motor 2 and corresponds to the parallel surface 54 of the first embodiment. The vertical surface 58 is arranged to be in parallel to the rotational axis 0 of the electric motor 2. Each of the power modules 60 is arranged at the inclined surface 57 so as to be in parallel to the inclined surface 57. The power terminals 65 are arranged to be in parallel to the vertical surfaces 58.

The second embodiment has the same advantages to the first embodiment.

### Further Modifications

In the above embodiments, the power terminals 65 (the wiring portions) of the switching devices and the power-output terminals 23 (the stator-coil terminals) are provided so as to be overlapped in the radial direction. However, it may be so modified that the power terminals 65 (the wiring portions) of the switching devices and the power-input terminals 791 are provided so as to be overlapped in the radial direction. Alternatively, it may be so modified that the power terminals 65 (the wiring portions) of the switching devices, the power-output terminals 23 (the stator-coil terminals) and the power-input terminals 791 are provided so as to be overlapped in the radial direction.

In the above embodiments, the power board 70 (the printed circuit board) and the heat sink 50 (the metal chassis) are in contact with each other. In a modification, the power board 70 and the heat sink 50 may be separated by a small distance (for example, several μm to several 10 μm), to the extent that the magnetic field is not propagated to the outside.

In the above embodiments, the electric motor is used as an electric load. Any other electric or electronic apparatuses or devices may be used as the electric load.

In the above embodiments, the driving apparatus 1 is applied to the electrical power steering device for the vehicle. The driving apparatus may be applied to any other apparatuses and/or devices.

In the above embodiments, the control board 40 is made of the glass-epoxy boards, while the power board 70 is made of the glass-epoxy boards having thick beaten-copper patterns. In a modification, the control board as well as the power board may be formed of bus bars and so on.

The present disclosure should not be limited to the above embodiments and/or modification, but may be modified in various manners without departing from the spirit of the present disclosure.

What is claimed is:

1. A control unit for controlling an electric load comprising:
a power-input terminal to be connected to a power source;
a power-output terminal connected to the electric load;
multiple switching devices provided between the power-input terminal and the power-output terminal for switching on or switching off power supply to the electric load;
wiring portions for electrically connecting the switching devices to the power-input terminal and the power-output terminal; and
a metal chassis for supporting the switching devices and having a parallel surface which is in parallel to the switching devices and the wiring portions,
wherein the wiring portions are magnetically coupled to at least one of the power-input terminal and the power-output terminal, when electric current flowing through the wiring portions is changed, and
wherein the switching devices and the wiring portions are arranged so as to be in parallel to the parallel surface of the metal chassis, in order that a magnetic field generated by electric current flowing through the switching devices and the wiring portions is cancelled by a magnetic field generated by eddy current flowing in the metal chassis.

2. The control unit according to claim 1, wherein
the wiring portions and the power-output terminals are electrically connected to a common printed circuit board.

3. The control unit according to claim 2, wherein
the metal chassis is in contact with the printed circuit board.

4. The control unit according to claim 2, wherein
the metal chassis is electrically connected to a ground portion, through which the printed circuit board is electrically connected to the ground.

5. The control unit according to claim 1, wherein
the switching devices forming an inverter circuit are integrally molded in one molded portion.

6. A driving apparatus comprising:
an electric motor; and
the control unit according to claim 1, which is provided at an axial end of the electric motor for controlling an operation of the electric motor,
wherein the switching devices are arranged on such a switching-device plane which intersects with a virtual plane perpendicular to a rotational axis of the electric motor, and
wherein the wiring portions are overlapped with at least one of the power-input terminal and the power-output terminal in a radial direction of the electric motor.

7. The driving apparatus according to claim 6, wherein
the switching-device plane is perpendicular to the virtual plane.
